(19) United States
(12) Patent Application Publication
(10) Pub. No.: US 2026/0190501 A1
(43) Pub. Date: Jul. 2, 2026

(54) ELECTROSTATIC DISCHARGE PROTECTION CIRCUIT WITH LOWER TRIGGER VOLTAGE AND REDUCED INPUT/OUTPUT CAPACITANCE

(71) Applicant: SAMSUNG ELECTRONICS CO., LTD., Suwon-si (KR)

(72) Inventors: Mitesh GOYAL, Bengaluru (IN); Mukesh CHATURVEDI, Bengaluru (IN); Mahesh VAIDYA, Bengaluru (IN); Mayank SHRIVASTAVA, Bengaluru (IN)

(73) Assignees: SAMSUNG ELECTRONICS CO., LTD., Suwon-si (KR); INDIAN INSTITUTE OF SCIENCE, Bangalore (IN)

(21) Appl. No.: 19/375,938

(22) Filed: Oct. 31, 2025

(30) Foreign Application Priority Data
Dec. 30, 2024 (IN) 202441104639
Sep. 27, 2025 (IN) 202441104639

(51) Int. Cl. H10D 89/60

(52) U.S. Cl. CPC H10D 89/713

(57) ABSTRACT

There is provided an Electrostatic Discharge (ESD) protection circuit including a Silicon Controlled Rectifier (SCR). The SCR includes an N+ diffusion region (Npick terminal), formed in an n-well (NW) region, and connected to a source terminal of a P-channel Metal Oxide Semiconductor (PMOS) transistor of an inverter, and a P+ diffusion region (Ptrig terminal), formed in a p-type substrate, and connected to a source terminal of an N-channel Metal Oxide Semiconductor (NMOS) transistor of the inverter.

### CROSS-REFERENCE TO RELATED APPLICATIONS

This application is based on and claims priority under 35 U.S.C. § 119 to Indian Patent Application No. 202441104639 filed on Sep. 27, 2025, and Indian Provisional Patent Application No. 202441104639 filed on Dec. 30, 2024, the disclosures of which are incorporated herein by reference in their entireties.

### BACKGROUND

### 1. Field

The disclosure relates to the field of electronic devices, and more specifically, to an Electrostatic Discharge (ESD) protection circuit with a lower trigger voltage and a reduced input/output (I/O) capacitance.

### 2. Description of Related Art

The information described in this background section is only for enhancement of understanding of the general background of the disclosure and should not be taken as an acknowledgement or any form of suggestion that this information forms the prior art already known to a person skilled in the art.

A Silicon-Controlled Rectifier (SCR) is a semiconductor device that serves as a controlled switch, and includes four layers of alternating p-type and n-type materials that form three PN-junctions. The SCR is a popular choice for Electrostatic Discharge (ESD) protection due to its low capacitance per unit area and ability to handle high failure currents. However, the SCR does have some drawbacks, including deep snapback issues, high voltage overshoots, and slower turn-on times compared to other ESD protection devices. While on-chip ESD protection devices, such as diodes, Ground-Gated N-channel Metal-Oxide Semiconductor (GGNMOS) transistors, and RC power clamps tend to occupy a large amount of chip area, SCRs are among the most area-efficient ESD protection devices available. Unlike traditional ESD diodes and power clamps, which conduct current primarily through holes from the P+/N-W junction, the SCRs allow current to flow from both electrons in the N+/P-W junction and holes in the P+/N-W junction. As such, the SCRs can provide the same level of ESD protection as standard diodes while taking up less space and having lower capacitance, making them particularly suitable for modern high-speed serial (e.g., Serializer/Deserializer (SERDES)) interfaces.

As Complementary Metal-Oxide-Semiconductor (CMOS) technology continues to scale down, operating voltages are decreasing, and gate oxide thickness is becoming thinner. This has led to a reduction in gate oxide breakdown voltage, creating a tighter design window for ESD protection devices. Therefore, a holding voltage (Vₕ) and a trigger voltage (Vₜ₁) of the ESD protection devices must be carefully designed to fit within this limited range to ensure effective protection without compromising the performance of an integrated circuit.

### SUMMARY

This summary is provided to introduce a selection of concepts, in a simplified format, that are further described in the detailed description of the inventive concept. This summary is neither intended to identify key or essential inventive concepts of disclosure nor is it intended for determining the scope of the inventive concept.

According to an aspect of the disclosure, there is provided an Electrostatic Discharge (ESD) protection circuit including: a trigger circuit including a resistor, a capacitor, and an inverter, and a Silicon Controlled Rectifier (SCR) including: an N+ diffusion region (Npick terminal), formed in an n-well (NW) region, the Npick terminal connected to a first output of the inverter or to a source terminal of a P-channel Metal Oxide Semiconductor (PMOS) transistor of the inverter, based on a clamping configuration; a P+ diffusion region (Ptrig terminal), formed in a p-type substrate, the Ptrig terminal connected to a second output of the inverter or to a source terminal of an N-channel Metal Oxide Semiconductor (NMOS) transistor of the inverter, based on the clamping configuration; and a power clamp connected between a Supply Voltage (VDD) terminal and a Ground (VSS) terminal and configured to clamp a voltage to a safe level, wherein the trigger circuit is configured to activate the SCR based on a detection of an ESD pulse.

According to another aspect of the disclosure, there is provided a Silicon Controlled Rectifier (SCR) including: an N+ diffusion region (Npick terminal) formed in an n-well (NW) region, the Npick terminal connected to an output of an inverter or to a source terminal of a P-channel Metal Oxide Semiconductor (PMOS) transistor of the inverter, based on a clamping configuration; and a P+ diffusion region (Ptrig terminal) formed in a p-type substrate, the Ptrig terminal connected to an output of the inverter or to a source terminal of an N-channel Metal Oxide Semiconductor (NMOS) transistor of the inverter, based on the clamping configuration, wherein the clamping configuration includes at least one of a VDD-IO clamping configuration and an IO-VSS clamping configuration.

According to another aspect of the disclosure, there is provided a method for protecting against Electrostatic Discharge (ESD), the method including: detecting an ESD pulse using a trigger circuit including a resistor, a capacitor, and an inverter; activating a Silicon Controlled Rectifier (SCR) based on the ESD pulse, the SCR including an N+ diffusion region (Npick terminal) formed in a n-well (NW) region, and connected to an output of the inverter or to a source terminal of P-channel Metal Oxide Semiconductor (PMOS) transistor of the inverter, and a P+ diffusion region (Ptrig terminal) formed in a p-type substrate, and connected to an output of the inverter or to a source terminal of N-channel Metal Oxide Semiconductor (NMOS) transistor of the inverter; and engaging a power clamp that limits a voltage to a safe level to prevent excessive damage by utilizing the SCR based on a clamping configuration, the power clamp connected between a Supply Voltage (VDD) terminal and a Ground (VSS) terminal.

To further clarify the advantages and features of the present invention, a more particular description of the invention will be rendered by reference to specific embodiments thereof, which are illustrated in the appended drawings. It is appreciated that these drawings depict only typical embodiments of the invention and are therefore not to be considered limiting of its scope. The invention will be described and explained with additional specificity and detail in the accompanying drawings.

### BRIEF DESCRIPTION OF DRAWINGS

These and other features, aspects, and advantages of the present invention will become better understood when the following detailed description is read with reference to the accompanying drawings in which like characters represent like parts throughout the drawings, wherein:

FIG. 1 illustrates a Two-Dimensional (2D) cross-section of a STI-bounded Silicon-Controlled Rectifier (SCR) device with a parasitic circuit diagram, according to a related art;

FIG. 2 illustrates an Electrostatic Discharge (ESD) protection circuit for an input or output pad with P_STSCR and N_STSCR devices, according to a related art;

FIGS. 3 and 4 illustrate one or more functionalities associated with an IO to VSS clamp circuit and a 2D cross-section of the IO to VSS clamp circuit, according to a related art;

FIG. 5 illustrates one or more functionalities associated with an IO to VSS clamp circuit, with PMOS connected to a N_{pick} terminal of a Silicon-Controlled Rectifier (SCR) device to reduce a capacitance on an IO pin, according to an embodiment of the disclosure;

FIG. 6 illustrates a 2D cross-section of a Silicon-Controlled Rectifier (SCR) device, with the N_{pick} terminal between an anode terminal and an Ntap terminal, according to an embodiment of the disclosure;

FIG. 7 illustrates a top view of the disclosed IO to VSS clamp circuit, according to an embodiment of the disclosure;

FIG. 8 illustrates a reference VDD to IO clamp circuit, according to a related art;

FIG. 9 illustrates one or more functionalities associated with the disclosed VDD to IO clamp circuit, wherein an NMOS source of a trigger circuit is connected to a P_{trig} terminal, according to an embodiment of the disclosure;

FIG. 10 illustrates a complete protection concept with a full ESD protection concept along with VDD to VSS power clamp, according to an embodiment of the disclosure; and

FIG. 11 is a flow diagram illustrating a method for protecting against ESD, according to an embodiment of the disclosure.

Further, skilled artisans will appreciate that elements in the drawings are illustrated for simplicity and may not have necessarily been drawn to scale. For example, the flow charts illustrate the method in terms of the most prominent operations or steps involved to help to improve understanding of aspects of the present invention. Furthermore, in terms of the construction of the device, one or more components of the device may have been represented in the drawings by conventional symbols, and the drawings may show only those specific details that are pertinent to understanding the embodiments of the present invention so as not to obscure the drawings with details that will be readily apparent to those of ordinary skill in the art having the benefit of the description herein.

### DETAILED DESCRIPTION

For the purpose of promoting an understanding of the principles of the inventive concept, reference will now be made to the embodiment illustrated in the drawings and specific language will be used to describe the same. It will nevertheless be understood that no limitation of the scope of the inventive concept is thereby intended, such alterations and further modifications in the illustrated system, and such further applications of the principles of the inventive concept as illustrated therein being contemplated as would normally occur to one skilled in the art to which the inventive concept relates.

It will be understood by those skilled in the art that the foregoing general description and the following detailed description are explanatory of the inventive concept and are not intended to be restrictive thereof.

Reference throughout this specification to “an aspect”, “another aspect” or similar language means that a particular feature, structure, or characteristic described in connection with the embodiment is included in at least one embodiment of the disclosure. Thus, appearances of the phrase “in an embodiment”, “in one embodiment”, “in another embodiment”, and similar language throughout this specification may, but do not necessarily, all refer to the same embodiment.

The terms “comprise”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components. As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. Also, the various embodiments described herein are not necessarily mutually exclusive, as some embodiments can be combined with one or more other embodiments to form new embodiments. The term “or” as used herein, refers to a non-exclusive or unless otherwise indicated. The examples used herein are intended merely to facilitate an understanding of ways in which the embodiments herein can be practiced and to further enable those skilled in the art to practice the embodiments herein. Accordingly, the examples should not be construed as limiting the scope of the embodiments herein.

As is traditional in the field, embodiments may be described and illustrated in terms of blocks that carry out a described function or functions. These blocks, which may be referred to herein as units or modules or the like, are physically implemented by analog or digital circuits such as logic gates, integrated circuits, microprocessors, microcontrollers, memory circuits, passive electronic components, active electronic components, optical components, hardwired circuits, or the like, and may optionally be driven by firmware and software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the inventive concept. Likewise, the blocks of the embodiments may be physically combined into more complex blocks without departing from the scope of the inventive concept.

The accompanying drawings are used to help easily understand various technical features and it should be understood that the embodiments presented herein are not limited by the accompanying drawings. As such, the disclosure should be construed to extend to any alterations, equivalents, and substitutes in addition to those which are particularly set out in the accompanying drawings. Although the terms first, second, etc. may be used herein to describe various elements, these elements should not be limited by these terms. These terms are generally only used to distinguish one element from another.

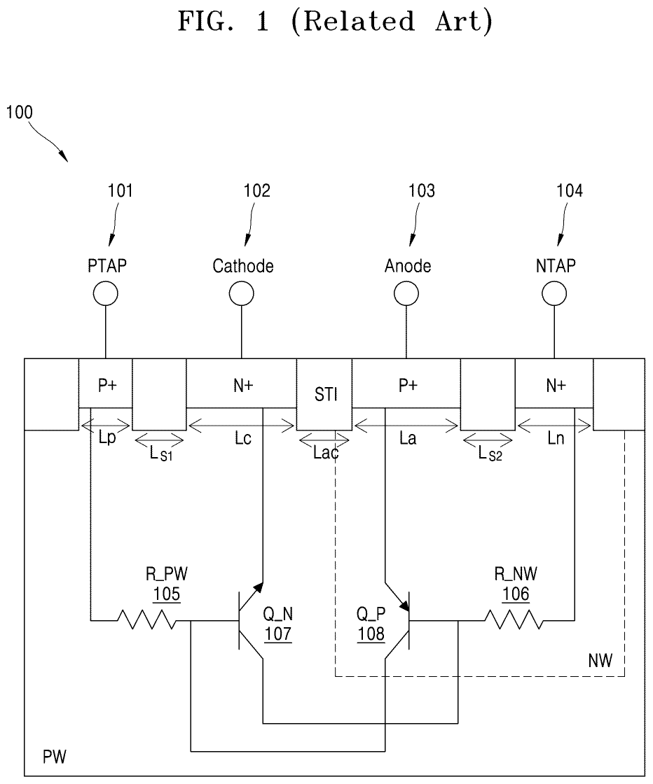

FIG. 1 illustrates a Two-dimensional (2D) cross-section of a Shallow Trench Isolation (STI)-bounded Silicon-Controlled Rectifier (SCR) device 100 with a parasitic circuit diagram, according to related art. The key components of the STI-bounded SCR device 100 may include, for example, a P-type Tap (PTAP) 101, a cathode 102, an anode 103, and an N-type Tap (NTAP) 104. The PTAP 101 is a P-type tap region for biasing the p-well, which serves as one of the terminals of the SCR. The cathode 102 is a negative terminal of the SCR. The anode 103 is a positive terminal of the SCR. The NTAP 104 is an N-type tap region for biasing the n-well region, which serves as another terminal of the SCR. The STI-bounded SCR device 100 may include one or more parasitic resistors, for example, a parasitic resistor in P-Well (R_PW) 105, a parasitic resistor in N-Well (R_NW) 106, and one or more parasitic Bipolar Junction Transistors (BJTs) (e.g., Q_N 107 and Q_P 108).

The STI-bounded SCR device 100 may operate based on the interaction between these components, which form a complex circuit. In an example case in which an ESD event occurs, the STI-bounded SCR device 100 is designed to trigger and provide a low-impedance path to safely discharge the excessive electrostatic charge, protecting the sensitive electronic components connected to the circuit. The parasitic elements, such as the BJT (e.g., Q_N 107 and Q_P 108) and the resistors (R_PW 105 and R_NW 106), play a crucial role in the functionality and performance of the STI-bounded SCR device 100. These parasitic elements can influence the trigger voltage (Vₜ₁), holding voltage (Vₕ), and overall ESD protection capabilities of the STI-bounded SCR device 100. The design and optimization of the SCR structure, including the parasitic components, are essential to ensure effective ESD protection while minimizing any adverse effects on the overall circuit performance.

In most modern low-voltage applications, the holding voltage (Vₕ) for the SCRs is higher than the operating voltage of CMOS devices. This characteristic leads to an advantageous latch-up-free ESD protection concept, as the SCR remains in a non-conducting state during normal circuit operation, effectively isolating the protected device from the ESD event. However, the trigger voltage (Vₜ₁) of a related art SCR (e.g., 100) is often higher than the gate oxide breakdown voltage in lower technology nodes. The trigger voltage (Vₜ₁) of the STI-bounded SCR device 100 must lie within the safe operating region of the protected devices to ensure effective and reliable ESD protection.

The STI-bounded SCR device 100 operates in two distinct states. In its high-impedance state, the STI-bounded SCR device 100 primarily presents drawbacks such as capacitance and leakage to a protected circuit. Conversely, upon the arrival of an ESD pulse, the STI-bounded SCR device 100 transitions to a latched low-impedance state, creating a low-resistance path that facilitates charge flow from the pulsing pins. During ESD stress on the anode 103, an avalanche breakdown of the p-n junction predominantly governs current conduction. This process results in excess electrons traversing the base of the PNP transistor, thereby activating the PNP transistor. The regenerative feedback mechanism between the NPN and PNP transistors enables SCR activation, which subsequently inundates the n-well with injected electrons, leading to an electron concentration that exceeds the doping level of the n-well. This shift in the electric field away from the well junction signifies Space Charge Modulation (SCM). However, as the conduction current density increases, so does the lattice temperature. If the lattice temperature surpasses the melting point of silicon, irreversible damage to the STI-bounded SCR device 100 occurs.

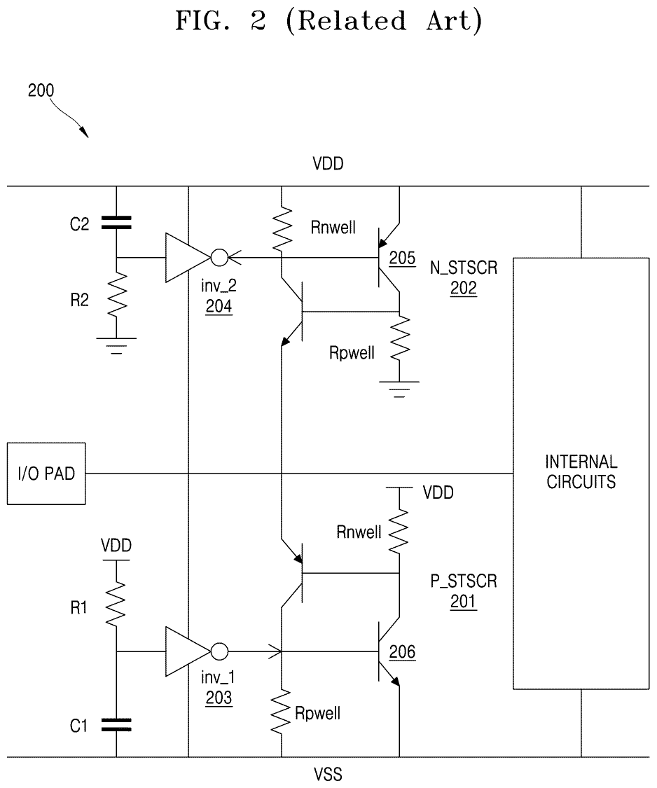

Although numerous low-triggering circuits have been proposed recently, many of these circuits are incompatible with contemporary CMOS technology or fail to maintain the trigger voltage within the ESD design window. Related art substrate triggering methods operate on the principle that applying current to the SCR substrate base can rapidly switch the device into its low-impedance state. In addition, FIG. 2 illustrates an ESD protection circuit 200 for input or output pads utilizing p-type silicon-controlled rectifier (P_STSCR) 201 and n-type silicon-controlled rectifier (N_STSCR) 202 devices. The P_STSCR 201 is a IO-VSS local clamp and N_STSCR 202 is IO-VDD local clamp for clamping the ESD surge voltage to safe levels. Under normal operating conditions with VDD and VSS power supplies, one or more inputs of inverter 1 (inv_1) 203 and inverter 2 (inv_2) 204 are biased at VDD and VSS, respectively. Consequently, the outputs of inv_1 203 and inv_2 204 are biased at VSS and VDD due to the activation of NMOS 205 and PMOS 206 transistors in inv_1 203 and inv_2 204, respectively, based on the logic levels of one or more input signals.

In an event of positive-to-VSS (PS) ESD stress (with VSS grounded and VDD floating), the input of inv_1 203 initially floats at zero volts, causing the PMOS transistor 206 in inv_1 203 to activate due to the positive ESD voltage at the pad. This results in the output of inv_1 203 being charged by the ESD energy, generating trigger current to the p-trigger node of the P_STSCR device 201, thus activating the P_STSCR device 201 and allowing ESD current to discharge from the I/O pad to the grounded VSS pin. A similar operational principle applies to the N_STSCR device 202 under negative-to-VDD (ND) ESD conditions.

Under a Negative-to-VSS mode (NS-mode) ESD stress condition, the P-well/N+ junction of the N_STSCR device 202 can be forward-biased to facilitate ESD current discharge. Similarly, under a Positive-to-VDD mode (PD-mode) ESD stress condition, the P+/N-well junction of the P_STSCR device 201 can also be forward-biased for ESD current discharge. Furthermore, the introduction of a dummy-gate structure within the STSCR device has been proposed to further minimize switching voltage.

Several challenges or limitations are encountered in the related art techniques illustrated in FIG. 1 and FIG. 2. For example, while the related art techniques may effectively reduce trigger voltage within the ESD design window, the capacitance associated with the PMOS transistor 206 and P_STSCR device 201 trigger circuit contributes additional capacitance to the I/O pin. Likewise, the NMOS capacitance in N_STSCR device 202 adds to the I/O capacitance, resulting in an undesirable increase in extra capacitance that adversely affects high-speed Serializer/Deserializer (SERDES) I/O solutions. Moreover, a leakage current from the off-state PMOS transistor 206 to the VSS path is substantial and necessitates reduction. A similar leakage path occurs from the NMOS of inv_2 204 when the I/O pin is grounded while VDD is at its normal operating voltage. Another significant drawback of the related art techniques is the low holding voltage (Vₕ), which is detrimental to the efficacy of ESD protection circuit designs, potentially leading to latch-up immunity issues.

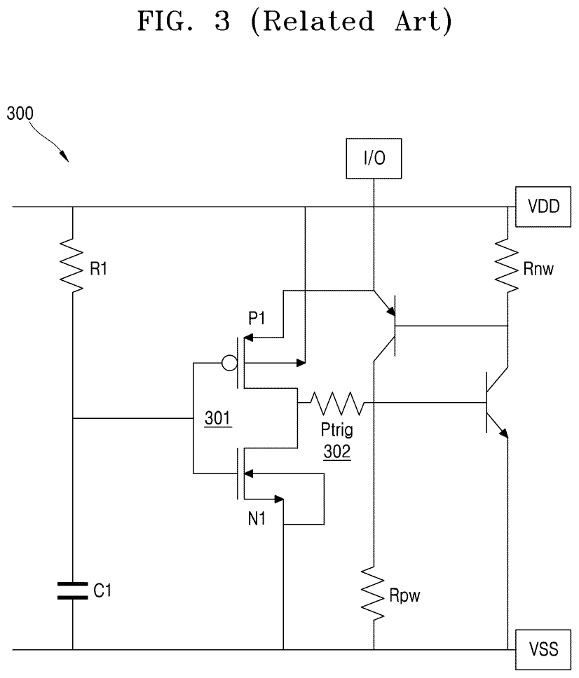

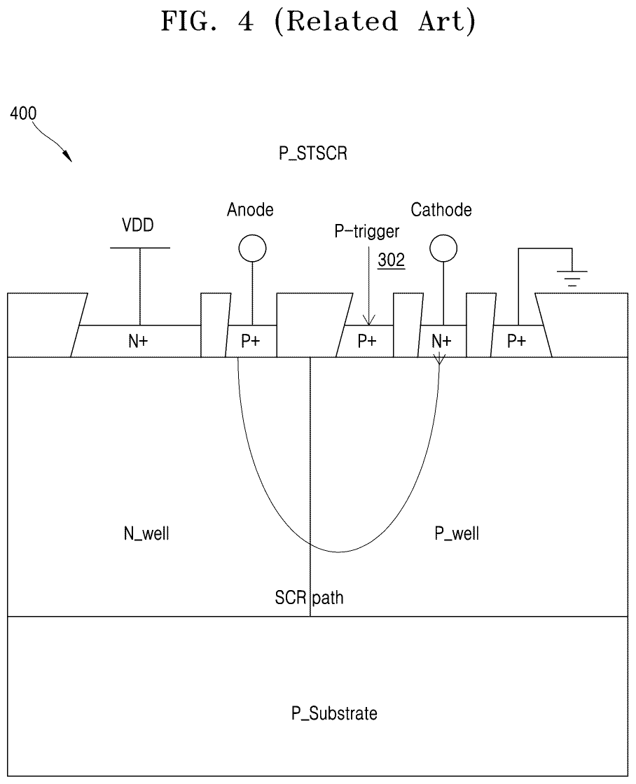

In the context of the I/O to VSS clamp, FIGS. 3 and 4 illustrate a configuration of an I/O to VSS pad. As illustrated in FIGS. 3 and 4 the I/O pin interfaces with an STI-bounded SCR, which is integrated with a triggering circuit comprising a CMOS inverter 301. During an electrostatic discharge (ESD) event, a PMOS transistor (P1) within the CMOS inverter 301 injects a triggering current directly into a P_{trig} terminal 302, as illustrated in FIG. 4. A source of the PMOS transistor (P1) is directly connected to the I/O pins, thus contributing its capacitance to the overall I/O capacitance, which is undesirable for high-speed applications. Additionally, there exists a leakage path from the I/O pin to the turn-off PMOS transistor (P1), subsequently routing to a drain of an NMOS transistor (N1). This NMOS transistor (N1) is connected to the VSS via an inversion channel. It is important to note that the NMOS transistor (N1) remains active during functional operation, with the PMOS transistor (P1) solely responsible for controlling leakage currents.

The related art techniques (e.g., FIG. 1 and FIG. 2) or the related art SCRs exhibit elevated trigger voltage levels, rendering them ineffective for ESD protection in thin gate devices. Variations in the manufacturing process result in substantial changes to a Process Design Kit (PDK), necessitating the development of a tunable Vₜ₁ SCR. The leakage current and on-resistance (Ron) of the SCR must be minimized. The related art techniques have addressed the issue of adjustable trigger voltage; however, they are compromised by increased capacitance and leakage current.

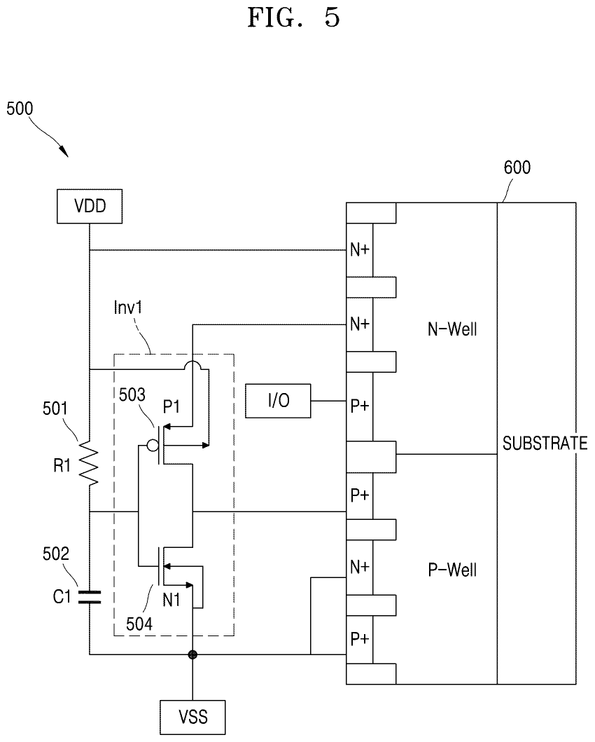

Thus, it is desired to address the above-mentioned disadvantages or other shortcomings or at least provide a useful alternative for the ESD protection circuit with the lower trigger voltage and reduced IO capacitance, as discussed throughout the disclosure (FIG. 5 to FIG. 7 and FIG. 9 to FIG. 10).

In some example embodiments, a substrate-triggering methodology aimed at reducing the triggering voltage (Vt1) of Silicon-Controlled Rectifier (SCR) devices is provided. This approach involves an in-depth examination of SCR device engineering, complemented by the implementation of both active and passive triggering circuits, validated through Technology Computer-Aided Design (TCAD) analysis and Transmission Line Pulse (TLP) measurements for ESD reliability.

In some example embodiments, the inbuilt diode of the SCR is utilized to create a new terminal. A novel SCR-based ESD protection concept has been developed, as discussed throughout the disclosure (FIG. 5 to FIG. 7 and FIG. 9 to FIG. 10), which disconnects the trigger circuit PMOS connection from the I/O pin and connects the trigger circuit PMOS to a newly formed terminal within the SCR device. The SCR device has been re-engineered to introduce a new terminal, referred to as N_{pick}, situated in the n-well region. Additionally, a complementary SCR structure is proposed for the VDD to I/O pin protection scheme. According to an embodiment, this SCR configuration reduces area requirements and lowers capacitance on the I/O pin. Furthermore, a series diode in the on state enhances the holding voltage (Vₕ).

FIGS. 5 to 11 illustrate one or more example embodiments of the inventive concept of the disclosure. In FIGS. 5 to 11, similar reference characters denote corresponding features consistently throughout the figures.

In one or more embodiments, the trigger circuit has been reworked, and a new (or another) terminal has been introduced in a new SCR device. For example, the new terminal may be referred to as the “N_{pick}” terminal. A cross-section of the new SCR according to an embodiment is shown in FIG. 5, which may represent an IO-VSS clamping configuration. The new terminal is introduced, for example, but is not limited to, between the anode and the NTAP terminal, thereby creating a low resistance path from the NTAP terminal to the N_{pick} terminal. According to an embodiment, the new SCR device utilizes an inbuilt p-n junction diode to tap the PMOS of the trigger circuit as shown in FIG. 5.

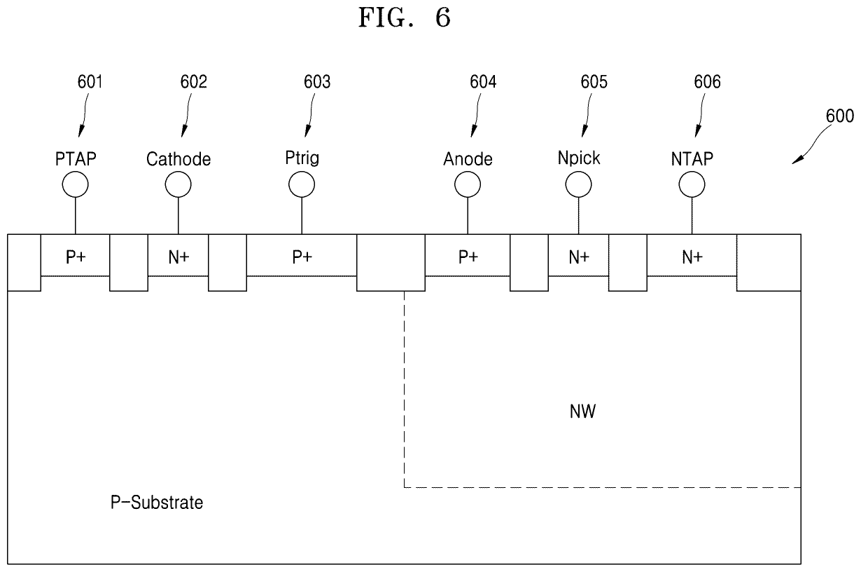

FIG. 5 illustrates one or more functionalities associated with the IO to VSS clamp circuit (I/O to VSS protection clamp), with PMOS transistor (P1) connected to the N_{pick} terminal of the SCR device to reduce the capacitance on the IO pin, according to an embodiment of the disclosure. The triggering circuit in I/O to VSS protection clamp includes the I/O rail, the VSS rail, a resistor (R1) 501, and a capacitor (C1) 502, a first inverter (Inv1) including the PMOS transistor (P1) 503 and NMOS transistor (N1) 504. The resistor (R1) 501 is connected in between the VDD rail and the common junction of capacitor (C1) 502 and gate of the inverter (Inv1), while the other end of capacitor (C1) 502 is connected to VSS rail. The bulk of PMOS transistor (P1) and NMOS transistor (N1) are connected to VDD and VSS rails respectively. Under normal operating conditions with VDD and VSS power supplies, the input of the Inv1 is biased at the VDD as the capacitor (C1) 502 is fully charged to DC VDD voltage. Accordingly, an output of the Inv1 is biased at the VSS due to an activation of an n-channel MOS (NMOS) transistor (N1). Under positive I/O to VSS ESD stress, the PMOS turns on and the output of inverter (Inv1) injects triggering current in the Ptrig terminal (e.g., 603 in FIG. 6) of the ESD protection device.

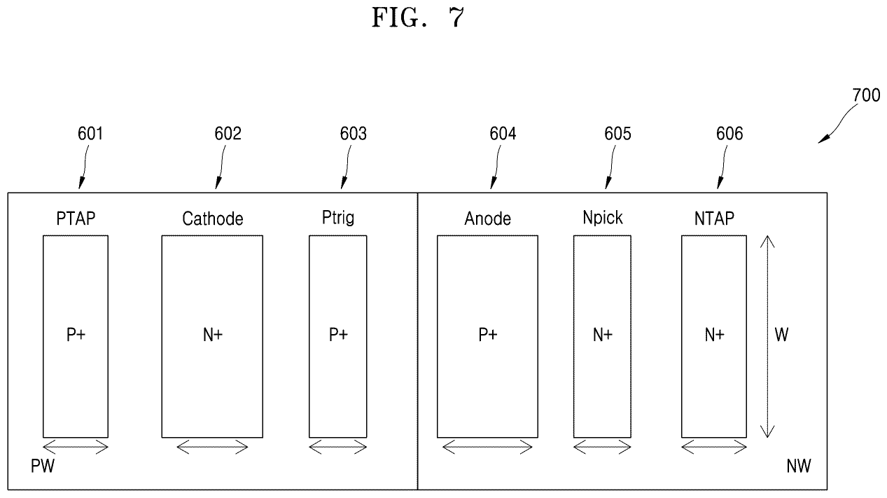

According to an embodiment, for this tap a new terminal in the SCR device, introduced by the name N_{pick} as shown in cross section view shown in FIG. 6 is utilized. The corresponding top view is shown in FIG. 7. Referring to FIG. 6, the trigger circuit may include, for example, a P-type Tap (PTAP) 601, a cathode 602, a P_{trig} terminal 603, an anode 604, a N_{pick} terminal 605 and an N-type Tap (NTAP) 606. The introduction of the N_{pick} terminal 605 and its subsequent connection to the PMOS transistor (P1) source of the trigger circuit, removes the capacitance from the IO pin and thereby reduces the capacitance. This is desirable for high-speed Serdes applications. In order to achieve the desirable Vₜ₁ of the CMOS-triggered SCR the PMOS transistor (P1) size is in the range of, for example, 10s of um, which contributes significantly to the capacitance of the IO pin.

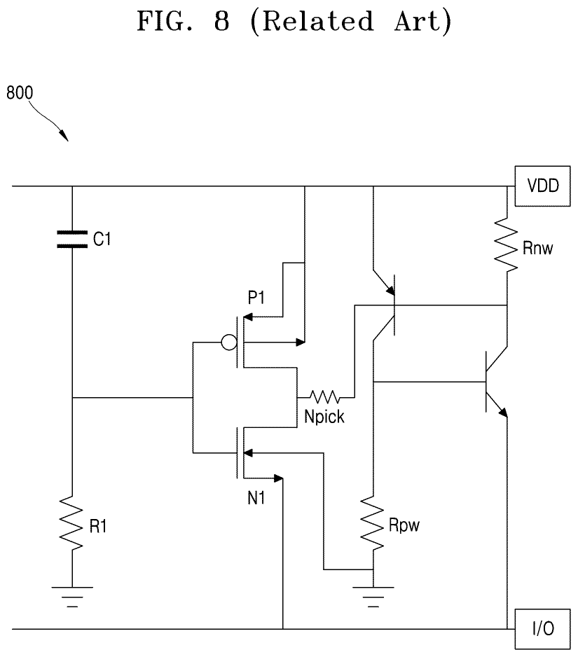

FIG. 8 illustrates a related art technology, in which, the VDD pin is connected to the STI-bounded SCR anode along with the trigger circuit which includes the CMOS inverter. In the CMOS inverter, during an ESD pulse, the NMOS transistor (N1) injects the trigger current directly into the IO terminal which is illustrated in FIG. 8. The NMOS transistor (N1) source is connected directly to the IO pins contributing its capacitance to the IO capacitance which is non-desirable for high-speed applications. Also, in the functional mode, the leakage path is from a highly connected VDD pin to a turned-off NMOS transistor (N1) and then to the source of the NMOS transistor (N1), which in turn is connected to the grounded IO pin. Note that the PMOS transistor (P1) also remains off in the functional mode and leakage is controlled by the NMOS transistor (N1).

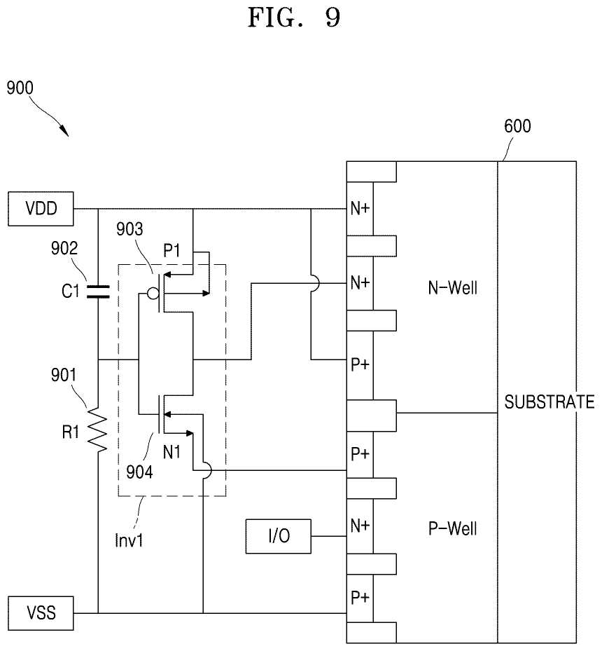

In one or more embodiments, the trigger circuit has been completely reworked, and introduced another terminal in the SCR device which is named the N_{pick} terminal 605; it is the same as described above in FIG. 6. According to an embodiment as illustrated in FIG. 9, the new SCR device utilizes an inbuilt p-n junction diode to tap the NMOS transistor (N1) source of the trigger circuit, which may represent a VDD-IO clamping configuration. The introduction of the N_{pick} terminal 605 and its subsequent connection to the NMOS transistor (N1) drain terminal and the connection of the NMOS transistor (N1) source to P_{trig} terminal 603 removes the capacitance on the IO pin, thereby reducing the capacitance of IO pin. This is desirable for high-speed Serializer/Deserializer (SerDes) applications. In order to achieve the desirable Vₜ₁ of the CMOS-triggered SCR, the NMOS transistor (N1) size is in the range of, for example, 10s of ums, which contributes significantly to the capacitance of the IO pin.

FIG. 9 illustrates one or more functionalities associated with the VDD to IO clamp circuit. According to an embodiment, the NMOS transistor (N1) source of the trigger circuit is connected to the P_{trig} terminal. The triggering circuit in VDD to I/O protection clamp includes the VDD rail, the VSS rail, a resistor (R1) 901, a capacitor (C) 902, and an inverter (Inv1) including a PMOS transistor (P1) 903 and a NMOS transistor (N1) 904. The resistor (R1) 901 is connected in between the VSS rail and the common junction of the capacitor (C1) 902 and gate of the inverter (Inv1), while the other end of capacitor (C1) 902 is connected to VDD rail. The bulk of PMOS transistor (P1) and NMOS transistor (N1) are connected to VDD and VSS rails respectively. NMOS transistor (N1) source is connected to the Ptrig terminal and common drain terminal of NMOS transistor (N1), PMOS transistor (P1) (output of inverter (Inv1)) is connected to the N_{pick} terminal. PMOS transistor (P1) source is connected to the VDD rail. Under normal operating conditions with VDD and VSS power supplies, the input of the Inv1 is biased at the VSS as the capacitor (C1) 902 is fully charged to DC VDD voltage. Consequently, an output of the Inv1 is biased at the VDD due to an activation of a PMOS transistor (P1). Under positive VDD to VSS ESD stress, the NMOS transistor (N1) turns on and injects triggering current in the Ptrig terminal of the ESD protection device.

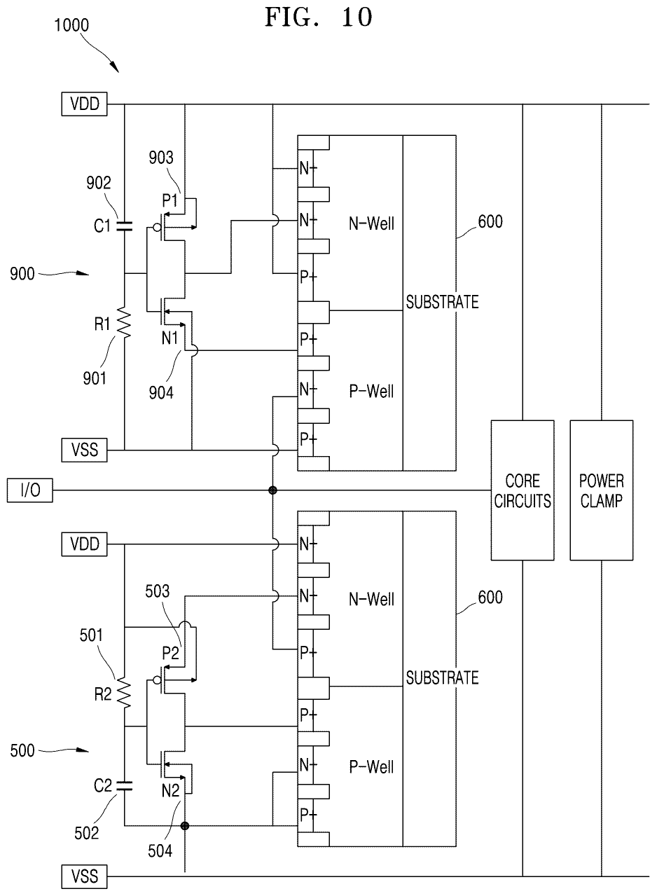

In some example embodiments, both the local clamps IO to VSS (related to FIG. 5) and VDD to IO (related FIG. 9), along with the power clamp (VDD to VSS) (1000) are generally used to form a complete ESD protection circuit as shown in FIG. 10. The same scheme can be extended to multi-IO pin concepts. In one embodiment, one or more core circuits may be generally the I/O pads where the receiver and transmitter signals are obtained. In place of Internal circuits, it may be power clamp which provides protection for ESD surges between VDD and VSS.

In some example embodiments, the trigger circuit utilizes the N_{pick} terminal 605 and the P_{trig} terminal 603 in an IO to VSS clamp. The N_{pick} terminal 605 is connected to the source of a PMOS transistor (P1). The P_{trig} terminal 603 is connected to an inverter output.

In some example embodiments, the trigger circuit utilizes the N_{pick} terminal 605 and the P_{trig} terminal 603 in a VDD to IO clamp. The N_{pick} terminal 605 is connected to the drain of the PMOS transistor (P1) and the NMOS transistor (N1). The P_{trig} terminal 603 is connected to the drain of the NMOS transistor (N1) and PMOS transistor (P1) (output of the ESD detection/trigger circuit).

In some example embodiments, the ESD protection circuit 1000 comprises the trigger circuit and the power clamp. The trigger circuit may include a resistor, a capacitor, and an inverter. The trigger circuit is configured to activate the SCR upon detection of an ESD pulse. The power clamp is configured to clamp a voltage to a safe level to prevent excessive damage by utilizing the SCR. The power clamp is connected between the VDD terminal and the VSS terminal.

In ESD protection design (ESD protection circuit 1000), the term safe operating window (safe level) refers to the voltage range within which the chip can function reliably without damage. This range lies between, for example:
a. The maximum operating voltage during normal chip operation (e.g., 1.5V), and
b. The minimum breakdown voltage below which the chip's core circuits may fail due to the ESD event (e.g., 7V).
The role of ESD protection circuit 1000 is to clamp the voltage to safe levels between the forementioned minimum and maximum voltage levels.

In some example embodiments, the SCR may include the N+ diffusion region (N_{pick} terminal) 605 and the P+ diffusion region (P_{trig} terminal) 603. The N_{pick} terminal 605 is formed in an n-well (NW) region and connected to an output of the inverter or to a source terminal of the PMOS transistor (P1) of the inverter, based on the clamping configuration. The P_{trig} terminal 603 is formed in a p-type substrate and connected to an output of the inverter or to a source terminal of the NMOS transistor (N1) of the inverter, based on the clamping configuration.

In some example embodiments, the clamping configuration may include the VDD-IO clamping configuration 900 and the IO-VSS clamping configuration 500. The VDD-IO clamping configuration 900 clamps an ESD surge voltage between the power supply voltage (VDD) and the input/output (IO) pin. The IO-VSS clamping configuration 500 clamps the ESD surge voltage between the IO pin and ground (VSS).

In some example embodiments, for the VDD-IO clamping configuration 900, the N_{pick} terminal is connected to the drains of both PMOS transistor (P1) and NMOS transistor (N1).

In some example embodiments, for the VDD-IO clamping configuration 900, the P_{trig} terminal is connected to the source terminal of the NMOS transistor (N1).

In some example embodiments, for the IO-VSS clamping configuration 500, the N_{pick} terminal is connected to the source terminal of the PMOS transistor (P1).

In some example embodiments, for the IO-VSS clamping configuration 500, the Ptrig terminal is connected to the output of the inverter or drain terminals of the NMOS transistor (N1) and PMOS transistor (P1).

In some example embodiments, the N_{pick} terminal is located between the P+diffusion (anode) and the N-type Tap (NTAP) terminal within the n-well region (NW.

In some example embodiments, the N_{pick} terminal is located after the NTAP terminal within the n-well region (NW).

In some example embodiments, the N_{pick} terminal is located in an interstitial space between the P+ diffusion (anode) and a n-well/p-well (NW/PW) junction.

In some example embodiments, the P_{trig} terminal is located between the N+diffusion (cathode) and the P-type Tap (PTAP) terminal.

In some example embodiments, the P_{trig} terminal is located after the PTAP terminal within the P-type substrate.

In some example embodiments, the P_{trig} terminal is located in an interstitial space between the N+ diffusion (cathode) and the n-well/p-well (NW/PW) junction.

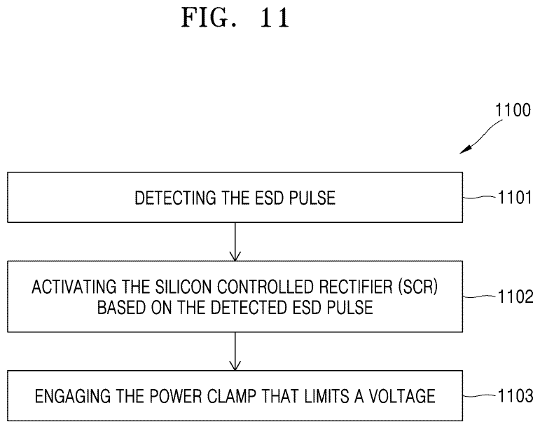

FIG. 11 is a flow diagram illustrating a method 1100 for protecting against ESD, according to an embodiment of the disclosure. The method 1100 may execute multiple operations to protecting against ESD, which are given below.

At operation 1101, the method 1100 may include detecting the ESD pulse. For example, the ESD pulse may be detected using the trigger circuit. At operation 1102, the method 1100 may include activating the SCR based on the detected ESD pulse. For example, the the SCR may be activated in response to the detected ESD pulse. At operation 1103, the method 1100 may include engaging the power clamp that limits the voltage based on the SCR. For example, the method 1100 may include engaging the power clamp that limits the voltage to a safe level to prevent excessive damage by utilizing the SCR. Further, a detailed description related to the various steps of FIG. 11 is covered in the description related to FIG. 5, FIG. 6, FIG. 7, FIG. 9, and FIG. 10, and is omitted herein for the sake of brevity.

In some example embodiments, the SCR device 600 may include one of: one or more shallow trench isolation (STI)-bound SCR junctions to separate one or more doped regions located within a volume of the SCR 600; or one or more dummy gate bounded SCR junctions to separate the one or more doped regions from a surface of the SCR 600.

The ESD protection circuit according to an embodiment of the disclosure and/or the method according to an embodiment of the disclosure has several advantages over the related art systems, which include, but is not limited to: (1) Improved efficiency: the Npick terminal provides a low-resistance path between the NTAP terminal to the Npick terminal, improving efficiency; (2) Reduced capacitance: Utilizing the inbuilt P-N junction diode helps shift capacitance from the IO pin to the VDD pin, lowering capacitance levels desirable for high-speed SERDES applications, and (3) Optimized PMOS and NMOS sizing: The design allows for PMOS and NMOS sizes in the range of tens of micrometres, balancing performance while minimizing capacitance contributions.

Unless otherwise defined, all technical and scientific terms used herein have the same meaning as commonly understood by one ordinary skilled in the art to which the embodiments of the inventive concept belong. The system, methods, and examples provided herein are illustrative only and not intended to be limiting.

While specific language has been used to describe the present subject matter, any limitations arising on account thereto, are not intended. As would be apparent to a person in the art, various working modifications may be made to the method to implement the inventive concept as taught herein. The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment.

One or more embodiments of the disclosure can be implemented using at least one hardware device and performing network management functions to control the elements.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the one or more embodiments of the disclosure. It is to be understood that the phraseology or terminology employed herein is for the purpose of description and not of limitation. Therefore, while the embodiments herein have been described in terms of one or more embodiments, those skilled in the art will recognize that the embodiments herein can be practiced with modification within the scope of the embodiments as described herein.

What is claimed is:

1. An Electrostatic Discharge (ESD) protection circuit comprising:
a trigger circuit comprising a resistor, a capacitor, and an inverter; and a Silicon Controlled Rectifier (SCR) comprising:
an N+ diffusion region (N_{pick} terminal), formed in an n-well (NW) region, the Npick terminal connected to a first output of the inverter or to a source terminal of a P-channel Metal Oxide Semiconductor (PMOS) transistor of the inverter, based on a clamping configuration;
a P+ diffusion region (P_{trig} terminal), formed in a p-type substrate, the P_{trig} terminal connected to a second output of the inverter or to a source terminal of an N-channel Metal Oxide Semiconductor (NMOS) transistor of the inverter, based on the clamping configuration; and
a power clamp connected between a Supply Voltage (VDD) terminal and a Ground (VSS) terminal and configured to clamp a voltage to a safe level,
wherein the trigger circuit is configured to activate the SCR based on a detection of an ESD pulse.

2. The ESD protection circuit as claimed in claim 1,
wherein the clamping configuration comprises at least one of a VDD-IO clamping configuration and an IO-VSS clamping configuration;
wherein the VDD-IO clamping configuration clamps an ESD surge voltage between a power supply voltage (VDD) and an input/output (IO) pin; and
wherein the IO-VSS clamping configuration clamps the ESD surge voltage between the IO pin and ground (VSS).

3. The ESD protection circuit as claimed in claim 2, wherein in the VDD-IO clamping configuration:
the N_{pick} terminal is connected to the output of the inverter, which is connected to a first drain terminal of the PMOS transistor and a second drain terminal of the NMOS transistor; and
the P_{trig} terminal is connected to the source terminal of the NMOS transistor.

4. The ESD protection circuit as claimed in claim 2, wherein in the IO-VSS clamping configuration:
the N_{pick} terminal is connected to a source terminal of the PMOS transistor; and
the Ptrig terminal is connected to the output of the inverter or drain terminals of the NMOS and PMOS.

5. The ESD protection circuit as claimed in claim 1, wherein the N_{pick} terminal is located between a P+ diffusion (anode) and a N-type Tap (NTAP) terminal within the n-well region (NW).

6. The ESD protection circuit as claimed in claim 1, wherein the N_{pick} terminal is located after an NTAP terminal within the n-well region (NW).

7. The ESD protection circuit as claimed in claim 1, wherein the N_{pick} terminal is located in a space between the P+ diffusion (anode) and an n-well/p-well (NW/PW) junction.

8. The ESD protection circuit as claimed in claim 1, wherein the P_{trig} terminal is located between a N+ diffusion (cathode) and a P-type Tap (PTAP) terminal.

9. The ESD protection circuit as claimed in claim 1, wherein the P_{trig} terminal is located after a PTAP terminal within the p-type substrate.

10. The ESD protection circuit as claimed in claim 1, wherein the P_{trig} terminal is located in a space between an N+ diffusion (cathode) and an n-well/p-well (NW/PW) junction.

11. A Silicon Controlled Rectifier (SCR) comprising:
an N+ diffusion region (Npick terminal) formed in an n-well (NW) region, the Npick terminal connected to an output of an inverter or to a source terminal of a P-channel Metal Oxide Semiconductor (PMOS) transistor of the inverter, based on a clamping configuration; and
a P+ diffusion region (Ptrig terminal) formed in a p-type substrate, the Ptrig terminal connected to an output of the inverter or to a source terminal of an N-channel Metal Oxide Semiconductor (NMOS) transistor of the inverter, based on the clamping configuration,
wherein the clamping configuration comprises at least one of a VDD-IO clamping configuration and an IO-VSS clamping configuration.

12. The SCR as claimed in claim 11,
wherein the VDD-IO clamping configuration clamps an ESD surge voltage between a power supply voltage (VDD) and an input/output (IO) pin; and
wherein the IO-VSS clamping configuration clamps the ESD surge voltage between the IO pin and ground (VSS).

13. The SCR as claimed in claim 11, wherein in the VDD-IO clamping configuration:
the N_{pick} terminal is connected to the output of the inverter, which is connected to drain terminals of both PMOS and NMOS transistors; and
the P_{trig} terminal is connected to the source terminal of the NMOS transistor.

14. The SCR as claimed in claim 11, wherein in the IO-VSS clamping configuration:
wherein the N_{pick} terminal is connected to a source terminal of the PMOS transistor; and
wherein the P_{trig} terminal is connected to the output of the inverter or drain terminals of the NMOS and PMOS.

15. The SCR as claimed in claim 11, comprises at least one of:
the N_{pick} terminal located between a P+ diffusion (anode) and an N-type Tap (NTAP) terminal within the n-well region (NW),
the N_{pick} terminal located after the NTAP terminal within the n-well region (NW) and the N_{pick} terminal located in an interstitial space between the P+ diffusion (anode) and a n-well/p-well (NW/PW) junction.

16. The SCR as claimed in claim 11, comprises at least one of:
the P_{trig} terminal located between an N+ diffusion (cathode) and a P-type Tap (PTAP) terminal,
the P_{trig} terminal located after the PTAP terminal within the P-type substrate, and
wherein P_{trig} terminal located in an interstitial space between the N+ diffusion (cathode) and an n-well/p-well (NW/PW) junction.

17. The SCR as claimed in claim 11, further comprises:
one or more shallow trench isolation (STI)-bound SCR junctions to separate one or more doped regions located within a volume of the SCR, or
one or more dummy gate bounded SCR junctions to separate the one or more doped regions from a surface of the SCR.

18. A method for protecting against Electrostatic Discharge (ESD), the method comprising:
detecting an ESD pulse using a trigger circuit comprising a resistor, a capacitor, and an inverter;
activating a Silicon Controlled Rectifier (SCR) based on the ESD pulse,
the SCR comprising
an N+ diffusion region (N_{pick} terminal) formed in a n-well (NW) region, and connected to a first output of the inverter or to a source terminal of P-channel Metal Oxide Semiconductor (PMOS) transistor of the inverter, and
a P+ diffusion region (P_{trig} terminal) formed in a p-type substrate, and connected to a second output of the inverter or to a source terminal of N-channel Metal Oxide Semiconductor (NMOS) transistor of the inverter; and
engaging a power clamp that limits a voltage to a safe level to prevent excessive damage by utilizing the SCR based on a clamping configuration, the power clamp connected between a Supply Voltage (VDD) terminal and a Ground (VSS) terminal.

19. The method of claim 18, wherein the clamping configuration comprises at least one of a VDD-IO clamping configuration and an IO-VSS clamping configuration;
wherein the VDD-IO clamping configuration clamps an ESD surge voltage between a power supply voltage (VDD) and an input/output (IO) pin; and
wherein the IO-VSS clamping configuration clamps the ESD surge voltage between the IO pin and ground (VSS).

20. The method of claim 19, wherein:
in the VDD-IO clamping configuration:
the N_{pick} terminal is connected to the output of the inverter, which is connected to a first drain terminal of the PMOS transistor and a second drain terminal of the NMOS transistor; and
the P_{trig} terminal is connected to the source terminal of the NMOS transistor, and
in the IO-VSS clamping configuration:
the N_{pick} terminal is connected to a source terminal of the PMOS transistor; and
the Ptrig terminal is connected to the output of the inverter or drain terminals of the NMOS and PMOS.
